(19) United States
(12) Patent Application Publication
(10) Pub. No.: US 2016/0138182 A1
(43) Pub. Date: May 19, 2016

(54) METHODS FOR FORMING MIXED METAL OXIDE EPITAXIAL FILMS

(71) Applicant: Wisconsin Alumni Research Foundation, Madison, WI (US)

(72) Inventor: Thomas F. Kuech, Madison, WI (US)

(21) Appl. No.: 14/546,199

(22) Filed: Nov. 18, 2014

(51) Int. Cl. C30B 1/02; C30B 29/26; H01L 21/02; C30B 29/68; H01L 29/20; C30B 29/20; C30B 29/40

(52) U.S. Cl. CPC C30B 1/023; C30B 29/20; C30B 29/26; C30B 29/406; C30B 29/68; H01L 29/2003; H01L 21/0254; H01L 21/02414

(57) ABSTRACT

Provided are methods for forming a mixed metal oxide epitaxial film (e.g., ScAlMgO₄) comprising growing an amorphous layer of a mixed metal oxide on a substrate (e.g., crystalline sapphire) via atomic layer deposition and annealing the amorphous layer of the mixed metal oxide at an elevated temperature for a period of time sufficient to induce epitaxial solid-state re-growth of the amorphous layer of the mixed metal oxide, thereby forming the mixed metal oxide epitaxial film. The method may further comprise growing a layer of a semiconductor (e.g., GaN) on the mixed metal oxide epitaxial film.

### BACKGROUND

The epitaxial growth of gallium nitride (GaN) and related materials is typically carried out on sapphire substrates since sapphire is low-cost and readily available. However, sapphire has both a thermal expansion mismatch and a large lattice parameter mismatch with GaN. These mismatches lead to a high density of dislocations and other defects in the semiconductor which detract from the performance of devices in which the semiconductor is incorporated. Lattice matched buffer layers have been used to improve the quality of the grown semiconductor. However, methods of forming such buffer layers suffer from drawbacks which have limited the improvements in the quality of the grown semiconductor.

### SUMMARY

Provided herein are methods for forming mixed metal oxide epitaxial films.

In one aspect, a method for forming a mixed metal oxide epitaxial film (e.g., ScAlMgO₄), comprises growing an amorphous layer of a mixed metal oxide on a crystalline substrate (e.g., sapphire) via atomic layer deposition, and annealing the amorphous layer of the mixed metal oxide at an elevated temperature for a period of time sufficient to induce epitaxial solid-state re-growth of the amorphous layer of the mixed metal oxide, thereby forming the mixed metal oxide epitaxial film. The method may further comprise growing a layer of a semiconductor (e.g., GaN) on the mixed metal oxide epitaxial film.

In another aspect, a multilayer structure comprises a crystalline substrate, a quaternary metal oxide epitaxial film on the surface of the crystalline substrate, the quaternary metal oxide composed of oxide anions, cations of a first metal, cations of a second metal and cations of a third metal, and a layer of a semiconductor on the surface of the quaternary metal oxide epitaxial film, wherein the quaternary metal oxide epitaxial film is single-phase and is substantially free of metal cations other than the cations of the first metal, the cations of the second metal and the cations of the third metal. Other multilayer structures are described below.

Other principal features and advantages of the invention will become apparent to those skilled in the art upon review of the following drawings, the detailed description, and the appended claims.

### BRIEF DESCRIPTION OF THE DRAWINGS

Exemplary embodiments of the invention will hereafter be described with reference to the accompanying drawings.

FIG. 1 depicts a method for forming a mixed metal oxide epitaxial film.

### DETAILED DESCRIPTION

A method for forming a mixed metal oxide epitaxial film may comprise growing an amorphous layer of a mixed metal oxide on a substrate via atomic layer deposition (ALD) and annealing the amorphous layer of the mixed metal oxide at an elevated temperature for a period of time sufficient to induce epitaxial solid-state re-growth of the amorphous layer of the mixed metal oxide, thereby forming the mixed metal oxide epitaxial film. As further described below, the mixed metal oxide epitaxial film may be used as a buffer layer for the subsequent growth of a layer of a semiconductor (e.g., a III-V nitride semiconductor as further described below), the semiconductor having a significant lattice mismatch with the substrate (e.g., an in-plane lattice mismatch at room temperature of at least ±10%, at least ±15%, at least ±17%, etc.). Thus, the disclosed methods may further include growing the layer of the semiconductor on the mixed metal oxide epitaxial film.

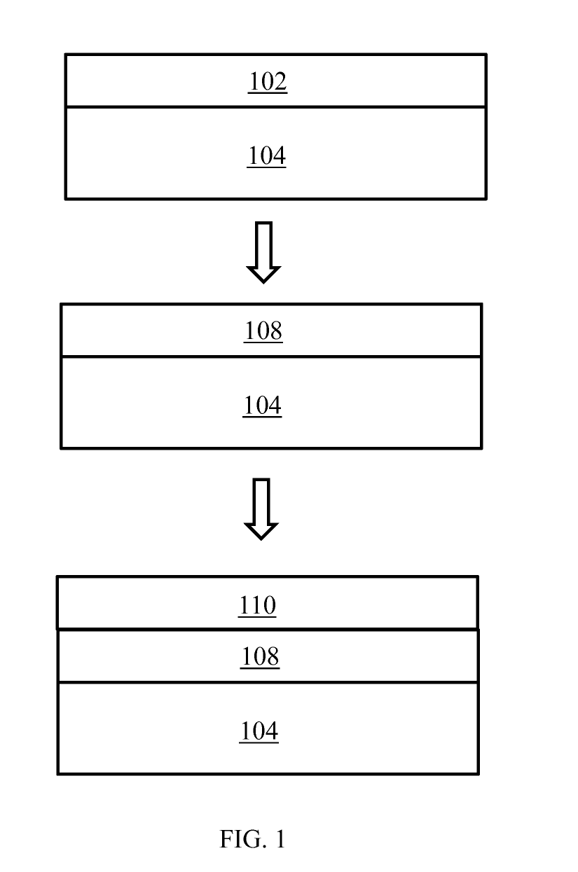

An exemplary method is illustrated in FIG. 1. In a first step, an amorphous layer of a mixed metal oxide 102 is grown directly on a crystalline substrate 104 via ALD. By “amorphous” it is meant that the layer 102 is non-crystalline substantially lacking in long range order. In a second step, the amorphous layer of the mixed metal oxide 102 is annealed at an elevated temperature for a period of time sufficient to induce epitaxial solid-state re-growth of the amorphous layer of the mixed metal oxide 102. The epitaxial solid-state re-growth crystallizes the amorphous layer of the mixed metal oxide 102, thereby providing the mixed metal oxide epitaxial film 108. By “epitaxial” it is meant that the crystal structure of the film 108 maintains a long-range structural and crystallographic relationship to the crystalline substrate 104. In a third step, a layer of a semiconductor 110 is grown directly on the mixed metal oxide epitaxial film 108.

By “mixed metal oxide,” it is meant a chemical compound composed of oxide anions and cations of more than one type of metal. As such, the disclosed mixed metal oxides are not binary metal oxides. However, by way of example, the mixed metal oxide may be a ternary metal oxide composed of oxide anions, cations of a first metal and cations of a second metal or a quaternary metal oxide composed of oxide anions, cations of a first metal, cations of a second metal and cations of a third metal. By “layer of a mixed metal oxide” it is meant that the layer is composed substantially entirely of the mixed metal oxide.

If the mixed metal oxide epitaxial film is to be used as a buffer layer for the subsequent growth of a layer of a semiconductor, the composition of the mixed metal oxide may be selected with consideration to the lattice mismatch of the mixed metal oxide with the selected semiconductor (e.g., a III-V nitride semiconductor as further described below). The mixed metal oxide may be that which has a lattice mismatch with the semiconductor which is significantly less than the lattice mismatch between the semiconductor and the substrate. For example, the in-plane lattice mismatch at room temperature between the mixed metal oxide and the semiconductor may be no more than ±5%, no more than ±2%, no more than ±1%, etc. However, the in-plane lattice mismatch at room temperature between the mixed metal oxide and the substrate may be at least ±6%, at least ±8%, at least ±10%, etc. Using such mixed metal oxides allows the lattice mismatch between the semiconductor and the substrate to be accommodated to defects in the mixed metal oxide epitaxial film, thereby providing a higher quality layer of semiconductor having reduced dislocations and other defects as compared to the layer of semiconductor grown directly on the lattice mismatched substrate without the buffer layer.

The mixed metal oxide may be characterized as being insulating, by which it is meant that the mixed metal oxide exhibits an electrical resistivity at room temperature similar to other known insulating materials such as glass. However, in other embodiments, the mixed metal oxide may be characterized as being conductive. An exemplary suitable conductive oxide is Sr₂RuO₄.

The mixed metal oxide may have the formula RAO₃(MO)ₙ, wherein R is a trivalent cation selected from Sc, In, Y, and the lanthanides; A is a trivalent cation selected from Fe(III), Ga and Al; M is a divalent cation selected from Mg, Mn, Fe(II), Co, Cu, Zn and Cd; and n is and integer ≧1. In some embodiments, the mixed metal oxide has the formula RAMO₄, wherein R, A and M are as defined above. In some embodiments, the mixed metal oxide has the formula RAM₃(MO)ₙ, wherein R, A and M are as defined above and n is 2, 3 or less than 9. Other suitable mixed metal oxides include Sc-based quaternary metal oxides, i.e., quaternary metal oxides having Sc as one of the metal cations, e.g., ScAM₃(MO)ₙ wherein A, M and n are defined as above. Specific suitable mixed metal oxides include ScAlMgO₄, ScGaMgO₄, InGaMgO₄, ScAlMnO₄, ScAlCoO₄ and InAlMgO₄. Other suitable mixed metal oxides include those described in U.S. Pat. No. 5,530,267, which is hereby incorporated by reference.

Other suitable mixed metal oxides include perovskite compounds (e.g., PbZrO₃) and spinel compounds (e.g., AlMgO₄).

As exemplified by the species of mixed metal oxide described above, the mixed metal oxide of the amorphous layers/epitaxial films may be a stoichiometric chemical compound, by which it is meant that the amount of non-stoichiometry in the chemical compound (the deviation of the elemental composition from non-integer values) is within the known phase stability region of the compound. Any amount of non-stoichiometry in such compounds may be so small as to not be measurable using standard chemical analytic techniques such as Energy-dispersive X-ray spectroscopy (EDS, EDX, or XEDS), sometimes called energy dispersive X-ray analysis (EDXA) or energy dispersive X-ray microanalysis (EDXMA), secondary ion mass spectroscopy (SIMS) or inductively coupled plasma atomic emission spectroscopy (ICP-AES). As further described below, this is possible because the use of ALD provides precise control over the stoichiometry of the grown layer of amorphous mixed metal oxide and because the step of epitaxial solid-state re-growth is non-reactive, i.e., the formation of the mixed metal oxide epitaxial film does not involve the chemical reaction of the amorphous mixed metal oxide with another compound which may provide a source of impurity metal cations in the mixed metal oxide (e.g., metal cations different from those represented in the ideal chemical formula for the mixed metal oxide). Similarly, the mixed metal oxide of the amorphous layers/epitaxial films may be substantially free of such impurity metal cations. For example, the mixed metal oxide which forms the amorphous layer and/or epitaxial film may be ScAlMgO₄ wherein the amorphous layer/epitaxial film is substantially free of metal cations other than Sc, Al and Mg cations. The mixed metal oxide which forms the amorphous layer and/or epitaxial film may be ScAlMgO₄ wherein the amorphous layer/epitaxial film is substantially free of Zn, Ga, or both.

In some embodiments, the mixed metal oxide is not ZnAOO₄. In some embodiments, the mixed metal oxide is not InGaO₃(ZnO)ₙ or ScGaO₃(ZnO)ₙ, wherein n≧2.

Mixed metal oxide epitaxial films having different thicknesses may be formed. Due to the use of ALD, very thin layers (e.g., a single or a few monolayers) of amorphous mixed metal oxide may be controllably grown. As described below, thicker layers may be grown by using multiple ALD cycles. The thickness of the mixed metal oxide epitaxial film may be no more than 100 nm, no more than 50 nm, no more than 20 nm, no more than 10 nm, no more than 5 nm, etc. The use of ALD also provides mixed metal oxide epitaxial films having uniform thicknesses. The thickness value for the mixed metal oxide epitaxial film may be an average thickness value with the deviation from this average thickness value being no more than ±10%, no more than ±5%, no more than ±2%, etc. across the surface of the film.

The mixed metal oxide epitaxial films may be characterized as being single-phase, by which it is meant that the film is composed substantially entirely of a single type of mixed metal oxide, e.g., rather than a mixture of the mixed metal oxide with another mixed metal oxide. The mixed metal oxide epitaxial films may also be characterized as being single-crystalline, by which it is meant that the film is composed substantially entirely of a single-crystal of the mixed metal oxide (rather than being polycrystalline).

The mixed metal oxide epitaxial films may be characterized by a dislocation density. The mixed metal oxide epitaxial films may have dislocation densities which are less than the dislocation densities in the films if the films were grown directly on sapphire. In some embodiments, the mixed metal oxide epitaxial films have a dislocation density of less than about 10⁹ cm⁻². Dislocation densities may be determined using transmission electron microscopy (TEM) or appropriate etch pit studies.

The amorphous layer of the mixed metal oxide may be grown over a variety of substrates, which may be crystalline, including single-crystalline. The substrate may be insulating wherein “insulating” has the same meaning with respect to an insulating mixed metal oxide as described above. An exemplary suitable substrate is sapphire or yttria stabilized zirconia. Other exemplary suitable substrates include silicon and GaAs. Other exemplary suitable substrates include LiNbO₃, LiTaO₃, and SiC.

Similarly, if the subsequently formed mixed metal oxide epitaxial film is to be used as a buffer layer for the growth of a layer of a semiconductor, a variety of semiconductors may be used. Exemplary suitable semiconductors include III-V nitride semiconductors, e.g., GaN, MN, InN, GaAlN, GaInN, AlInN, GaAlInN, etc. A small amount (e.g., less than 10 weight %) of As or P may substitute for N in the III-V nitride semiconductors. The layer of the semiconductor may be undoped or doped. Another exemplary suitable semiconductor is ZnO or ZnSe.

As described above, the amorphous layer of mixed metal oxide may be grown via ALD. ALD is a vapor phase deposition technique which relies on exposing a substrate supported in an ALD growth chamber to discrete, sequential pulses of gas-phase chemical precursors which act as sources for the chemical elements of the desired layer.

For purposes of illustrating the ALD technique, the growth of a binary metal oxide via ALD using a metal precursor and an oxygen precursor is as follows. The metal precursor may be high vapor pressure chemical compound, e.g., a metalorganic compound, comprising the metal corresponding to the metal cation of the desired binary metal oxide. The oxygen precursor is a chemical compound capable of oxidizing the metal precursor. For example, to form Al₂O₃, the metal precursor may be trimethylaluminum and the oxygen precursor may be H₂O. First, the substrate is exposed to a pulse of the metal precursor which reacts with active sites on the substrate in a first half reaction. Next, the growth chamber is purged (e.g., by an inert gas or evacuation at high vacuum) to remove any unreacted metal precursor and reaction byproducts. Next, the substrate is exposed to a pulse of the oxygen precursor which reacts with adsorbed metal precursor to form the binary metal oxide and regenerates active sites on the substrate in a second half reaction. Next, the growth chamber is purged. The two half-reactions constitute one complete cycle and provide a partial monolayer of the binary metal oxide on the substrate. Multiple cycles may be used to grow a complete monolayer of the binary metal oxide or a layer of the binary metal oxide having a desired thickness. The self-limiting nature of the half-reactions allows for control over chemical composition, thickness and conformality.

To grow the layer of the amorphous mixed metal oxide, multiple metal precursors may be used, e.g., a metal precursor for each type of metal cation in the desired mixed metal oxide. A variety of metalorganic compounds, e.g., metal alkoxides, may be used for the metal precursors, provided they have sufficiently high vapor pressures to volatilize and are sufficiently stable so as not to prematurely decompose in the ALD growth chamber. For example, in order to grow ScAlMgO₄, scandium tris(N,N-diisopropylacetamidinate) or Sc(methylcyclopentadienyl)₃ may be used as a first metal precursor to provide a source of Sc cations, trimethylaluminum may be used as a second metal precursor to provide a source of Al cations, and Mg(methylcyclopentadienyl)₂ may be used as a third metal precursor to provide a source of Mg cations. A variety of oxygen precursors may be used, e.g., water or ozone or another similar oxidizing agent.

The step of growing the amorphous layer of the mixed metal oxide on the substrate may include exposing the substrate supported in a growth chamber (i.e., one adapted for ALD) to alternating pulses of one or more of the metal precursors and the oxidizing precursor. In one embodiment, the substrate may be exposed to each of the metal precursors simultaneously, i.e., the metal precursor pulse is a co-pulse such that individual pulses of each metal precursor are delivered to the growth chamber at the same time, followed by purging the growth chamber. Next, the substrate may be exposed to a pulse of the oxygen precursor, following by purging the growth chamber. These steps constitute one complete ALD cycle and multiple ALD cycles may be used to grow a complete monolayer of the mixed metal oxide or a layer of the mixed metal oxide having a desired thickness.

In another embodiment, the substrate may be exposed to each of metal precursors individually, separated by exposure to the oxygen precursor. For example, first, the substrate may be exposed to a pulse of a first metal precursor, followed by purging the growth chamber. Next, the substrate may be exposed to a first pulse of the oxygen precursor, followed by purging the growth chamber. Next, the substrate may be exposed to a pulse of a second metal precursor, followed by purging the growth chamber. Next, the substrate may be exposed to a second pulse of the oxygen precursor, followed by purging the growth chamber. These steps are repeated as necessary until the substrate has been exposed to each metal precursor, each exposure to metal precursor followed by purging and exposure to the oxygen precursor. Together, the steps constitute one complete ALD cycle and multiple ALD cycles may be used to grow a complete monolayer of the mixed metal oxide or a layer of the mixed metal oxide having a desired thickness.

The pulse of each precursor may be characterized by a pulse time (corresponding to the time in which the substrate is exposed to the pulse) and pulse pressure (corresponding to the partial pressure of the precursor(s) in the growth chamber). Different pulse times and pulse pressures may be used depending upon the vapor pressure of the precursor, the composition of the mixed metal oxide and the substrate and the kinetics associated with the relevant surface chemical reactions. Suitable pulse times include pulse times from about 1 second to greater than a minute. Suitable pulse pressures include pulse pressures from about 10 mTorr to several Torr. Pulse pressures may also depend upon desired growth rates; growth rates may be higher as the total pressure in the growth chamber is decreased or as the ratio of the pulse pressure to the total pressure is increased. For embodiments in which the pulses of the metal precursors are delivered to the growth chamber simultaneously as a co-pulse, the different partial pressures of the metal precursors in the growth chamber may be used depending upon the composition of the mixed metal oxide. However, in such an embodiment, the partial pressures of each of the metal precursors in the growth chamber may be substantially equal.

The growth of the amorphous layer of mixed metal oxide via ALD may take place at an elevated temperature, e.g., 150-300° C., depending upon the composition of the mixed metal oxide and the substrate and the activation energies associated with the relevant surface chemical reactions. The elevated temperature may be achieved by heating the substrate.

Different purge times (the time the growth chamber is flushed with an inert gas or evacuated at high vacuum) may be used provided the time is sufficient to remove unreacted precursor and reaction byproducts. Suitable purge times include from about 10 seconds to about 1 minute.

As described above, the amorphous layer of the mixed metal oxide may be annealed at an elevated temperature for a period of time sufficient to induce epitaxial solid-state re-growth of the amorphous layer of the mixed metal oxide to form the mixed metal oxide epitaxial film. The temperature and time will depend upon the composition of the mixed metal oxide and the substrate. Suitable temperatures include about 1000° C. or a temperature in the range of from about 800° C. to about 1500° C. Suitable times include about one hour or a time in the range of from about 30 minutes to about 2 hours. The annealing step may be conducted in air at atmospheric pressure. By contrast to methods employing reactive solid-phase epitaxy, the disclosed annealing step does not involve the chemical reaction of the amorphous mixed metal oxide with another compound, e.g., with a compound in a layer or material in contact with the layer of the amorphous mixed metal oxide, to form the desired mixed metal oxide epitaxial film. As such, the disclosed methods are capable of providing purer, stoichiometric mixed metal oxide epitaxial films having fewer defects and higher quality interfaces with the underlying substrate.

If the mixed metal oxide epitaxial film is to be used as a buffer layer for the growth of a layer of a semiconductor, a variety of epitaxial growth techniques may be used to grow the layer of the semiconductor, e.g., metalorganic chemical vapor deposition (MOCVD) or molecular beam epitaxy (MBE).

Also provided are the multilayer structures formed using the disclosed methods (e.g., the mixed metal oxide epitaxial film/substrate structures and the semiconductor/mixed metal oxide epitaxial film/substrate structures). Exemplary multilayer structures include ScAlMgO₄/sapphire or ScAlMgO₄/yttria stabilized zirconia (which may be used to grow high quality group III-V nitride semiconductors) and GaN/ScAlMgO₄/sapphire or ZnO/ScAlMgO₄/yttria stabilized zirconia (which may be used in a variety of optoelectronic solid-state devices such as light emitting devices). Multilayer structures including a conductive mixed metal oxide on SiC may also be used to grow high quality group III-V nitride semiconductors, including GaN. Multilayer structures including mixed metal oxide epitaxial films on LiNbO₃ and related substrates may be used in a variety of nonlinear optical materials and related devices. Multilayer structures including perovskite epitaxial films on various substrates may be used in a variety of integrated actuators and sensors.

The word “exemplary” is used herein to mean serving as an example, instance, or illustration. Any aspect or design described herein as “exemplary” is not necessarily to be construed as preferred or advantageous over other aspects or designs. Further, for the purposes of this disclosure and unless otherwise specified, “a” or “an” means “one or more”.

The foregoing description of exemplary embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method for forming a mixed metal oxide epitaxial film, the method comprising:
growing an amorphous layer of a mixed metal oxide on a crystalline substrate via atomic layer deposition, and
annealing the amorphous layer of the mixed metal oxide at an elevated temperature for a period of time sufficient to induce epitaxial solid-state re-growth of the amorphous layer of the mixed metal oxide, thereby forming the mixed metal oxide epitaxial film.

2. The method of claim 1, wherein the mixed metal oxide is a quaternary metal oxide.

3. The method of claim 1, wherein the mixed metal oxide is one which has an in-plane lattice mismatch with a III-V nitride semiconductor of no more than ±5% at room temperature.

4. The method of claim 1, wherein the mixed metal oxide has the formula ScAMO₄, wherein A is a trivalent cation selected from Fe(III), Ga and Al and M is a divalent cation selected from Mg, Mn, Fe(II), Co, Cu, Zn and Cd.

5. The method of claim 4, wherein the mixed metal oxide is ScAlMgO₄.

6. The method of claim 1, wherein the crystalline substrate is one which has an in-plane lattice mismatch with a III-V nitride semiconductor of at least ±6% at room temperature.

7. The method of claim 1, wherein the crystalline substrate is sapphire.

8. The method of claim 1, wherein the mixed metal oxide is ScAlMgO₄ and the crystalline substrate is sapphire.

9. The method of claim 1, further comprising growing a layer of a semiconductor on the mixed metal oxide epitaxial film.

10. The method of claim 9, wherein the in-plane lattice mismatch between the crystalline substrate and the semiconductor is at least ±6% at room temperature and the in-plane lattice mismatch between the semiconductor and the mixed metal oxide is no more than ±5% at room temperature.

11. The method of claim 10, wherein the crystalline substrate is sapphire.

12. The method of claim 11, wherein the semiconductor is a III-V nitride semiconductor.

13. The method of claim 12, wherein the mixed metal oxide has the formula ScAMO₄, wherein A is a trivalent cation selected from Fe(III), Ga and Al and M is a divalent cation selected from Mg, Mn, Fe(II), Co, Cu, Zn and Cd.

14. The method of claim 13, wherein the mixed metal oxide is ScAlMgO₄ and the III-V nitride semiconductor is GaN.

15. A multilayer structure comprising:
a crystalline substrate,
a quaternary metal oxide epitaxial film on the surface of the crystalline substrate, the quaternary metal oxide composed of oxide anions, cations of a first metal, cations of a second metal and cations of a third metal, and
a layer of a semiconductor on the surface of the quaternary metal oxide epitaxial film,
wherein the quaternary metal oxide epitaxial film is single-phase and is substantially free of metal cations other than the cations of the first metal, the cations of the second metal and the cations of the third metal.

16. The multilayer structure of claim 15, wherein the quaternary metal oxide is one which has an in-plane lattice mismatch with a III-V nitride semiconductor of no more than ±5% at room temperature.

17. The multilayer structure of claim 15, wherein the quaternary metal oxide has the formula ScAMO₄, wherein A is a trivalent cation selected from Fe(III), Ga and Al and M is a divalent cation selected from Mg, Mn, Fe(II), Co, Cu, Zn and Cd.

18. The multilayer structure of claim 17, wherein the quaternary metal oxide is ScAlMgO₄.

19. The multilayer structure of claim 17, wherein the crystalline substrate is sapphire and the semiconductor is a III-V nitride semiconductor.

20. The multilayer structure of claim 19, wherein the quaternary metal oxide is ScAlMgO₄ and the III-V nitride semiconductor is GaN.
